(19) United States
(12) Patent Application Publication
(10) Pub. No.: US 2023/0420284 A1
(43) Pub. Date: Dec. 28, 2023

(54) METHOD FOR MANUFACTURING LIGHT-EMITTING DEVICE

(71) Applicant: NICHIA CORPORATION, Anan-shi (JP)

(72) Inventors: Kensuke YAMAOKA, Tokushima-shi (JP); Hiroki YUU, Anan-shi (JP)

(73) Assignee: NICHIA CORPORATION, Anan-shi (JP)

(21) Appl. No.: 18/329,646

(22) Filed: Jun. 6, 2023

(30) Foreign Application Priority Data
Jun. 23, 2022 (JP) 2022-100861

(51) Int. Cl. H01L 21/683; H01L 25/075; H01L 33/62

(52) U.S. Cl. CPC H01L 21/6835; H01L 25/0753; H01L 33/62; H01L 2221/68354; H01L 2221/68368; H01L 2221/68381; H01L 2933/0066

(57) ABSTRACT

A method for manufacturing a light-emitting device includes: preparing a first structure comprising: a first substrate having a first surface and a second surface on a side opposite the first surface, a release layer disposed on the first surface, and one or more light-emitting elements fixed to the first surface of the first substrate via the release layer, the one or more light-emitting elements each having a third surface facing the release layer and a fourth surface on a side opposite the third surface, the fourth surface being larger than the third surface in a plan view, wherein: the release layer encloses the fourth surface in the plan view; preparing a second structure comprising a second substrate having an upper surface; and transferring the one or more light-emitting elements from the first substrate to the second substrate by removing the release layer.

### CROSS-REFERENCE TO RELATED APPLICATIONS

The present application claims priority under 35 U.S.C. § 119 to Japanese Patent Application No. 2022-100861, filed Jun. 23, 2022, the contents of which are hereby incorporated by reference in their entirety.

### BACKGROUND

### 1. Technical Field

An embodiment of the present disclosure relates to a method for manufacturing a light-emitting device.

### 2. Description of Related Art

Japanese Patent Publication No. 2010-251359 discloses a light-emitting device in which a plurality of light-emitting elements are arranged on a substrate. Such a light-emitting device is required to have improved reliability.

### SUMMARY

An object of an embodiment of the present disclosure is to provide a method for manufacturing a light-emitting device with high reliability.

A method for manufacturing a light-emitting device according to an embodiment includes a step of preparing a first structure, a step of preparing a second structure, and a step of transferring one or more light-emitting elements. The first structure includes a first substrate having a first surface and a second surface on a side opposite the first surface, a release layer disposed on the first surface, and one or more light-emitting elements fixed to a side of the first surface of the first substrate via the release layer. The one or more light-emitting elements have a third surface facing the release layer and a fourth surface on a side opposite the third surface. The fourth surface is larger than the third surface in a plan view. The release layer encloses the fourth surface in the plan view. The second structure includes a second substrate having an upper surface. In the step of transferring the one or more light-emitting elements, the one or more light-emitting elements are transferred from the first substrate to the second substrate by removing the release layer in such a manner that the release layer is irradiated with laser light from a second surface side of the first substrate in a state in which the first surface of the first substrate is opposed to the upper surface of the second substrate such that the one or more light-emitting elements are disposed between the first substrate and the second substrate.

According to an embodiment of the present disclosure, it is possible to implement a method for manufacturing a light-emitting device with high reliability.

### BRIEF DESCRIPTION OF THE DRAWINGS

A more complete appreciation of embodiments of the disclosure and many of the attendant advantages thereof will be readily obtained by reference to the following detailed description when considered in connection with the accompanying drawings.

FIG. 1 is an end view schematically illustrating a method for manufacturing a light-emitting device according to a first embodiment.

FIG. 2 is an end view schematically illustrating the method for manufacturing the light-emitting device according to the first embodiment.

FIG. 3 is an end view schematically illustrating the method for manufacturing the light-emitting device according to the first embodiment.

FIG. 4 is an end view schematically illustrating the method for manufacturing the light-emitting device according to the first embodiment.

FIG. 5 is an end view schematically illustrating the method for manufacturing the light-emitting device according to the first embodiment.

FIG. 6 is an end view schematically illustrating the method for manufacturing the light-emitting device according to the first embodiment.

FIG. 7 is a plan view schematically illustrating the method for manufacturing the light-emitting device according to the first embodiment.

FIG. 8 is an end view taken along line VIII-VIII of FIG. 7.

FIG. 9 is an end view schematically illustrating the method for manufacturing the light-emitting device according to the first embodiment.

FIG. 10 is an end view schematically illustrating the method for manufacturing the light-emitting device according to the first embodiment.

FIG. 11 is an end view schematically illustrating the method for manufacturing the light-emitting device according to the first embodiment.

FIG. 12 is an end view schematically illustrating the method for manufacturing the light-emitting device according to the first embodiment.

FIG. 13 is an end view schematically illustrating the method for manufacturing the light-emitting device according to the first embodiment.

FIG. 14 is an end view schematically illustrating the method for manufacturing the light-emitting device according to the first embodiment.

FIG. 15 is an end view schematically illustrating the method for manufacturing the light-emitting device according to the first embodiment.

FIG. 16A is an end view schematically illustrating a rework process after the transfer of a light-emitting element.

FIG. 16B is an end view schematically illustrating the rework process after the transfer of the light-emitting element.

FIG. 16C is an end view schematically illustrating the rework process after the transfer of the light-emitting element.

FIG. 16D is an end view schematically illustrating the rework process after the transfer of the light-emitting element.

FIG. 17 is an end view schematically illustrating a method for manufacturing a light-emitting device according to a first modified example of the first embodiment.

FIG. 18 is an end view schematically illustrating the method for manufacturing the light-emitting device according to the first modified example of the first embodiment.

FIG. 19 is a view schematically illustrating a Galvano-laser device used in a second modified example of the first embodiment.

FIG. 20 is an end view schematically illustrating a method for manufacturing a light-emitting device according to the second modified example of the first embodiment.

FIG. 21 is a view illustrating an intensity distribution of laser light.

FIG. 22 is a perspective view schematically illustrating a light-emitting device according to a second embodiment when viewed from obliquely above.

FIG. 23 is a perspective view schematically illustrating the light-emitting device according to the second embodiment when viewed from obliquely below.

FIG. 24 is a partially enlarged top view illustrating a region XXIV of FIG. 22.

FIG. 25 is a cross-sectional view taken along line XXV-XXV of FIG. 22.

FIG. 26A is a partially enlarged cross-sectional view illustrating a region XXVIA of FIG. 25.

FIG. 26B is a partially enlarged cross-sectional view illustrating a region XXVIB of FIG. 26A.

FIG. 27A is an end view schematically illustrating a method for manufacturing the light-emitting device according to the second embodiment.

FIG. 27B is an end view schematically illustrating the method for manufacturing the light-emitting device according to the second embodiment.

### DETAILED DESCRIPTION

Methods for manufacturing light-emitting devices according to embodiments of the present disclosure are described below with reference to the drawings. The following embodiments are examples of embodying the technical concept of the present embodiment, and are not limited to the following. Dimensions, materials, shapes, relative arrangement, or the like of constituent members described in the embodiments are not intended to limit the scope of the present disclosure thereto, unless otherwise specified, and are merely exemplary. Note that the size, positional relationship, or the like of members illustrated in the drawings may be exaggerated for clarity of description. In the following description, the same names and reference numerals denote members that are the same or of the same quality, and a detailed description thereof is omitted as appropriate. As a cross-sectional view, an end view illustrating only a cut surface may be illustrated.

In the following description, terms indicating a specific direction or position (for example, “upper,” “lower,” and other terms including those terms) may be used. However, these terms are used merely to make it easy to understand relative directions or positions in the referenced drawing. As long as the relative directional or positional relationship is the same as that described in the referenced drawing using the term such as “upper” or “lower,” in drawings other than the drawings of the present disclosure, actual products, and the like, members may not be arranged as in the referenced drawing. For example, on the assumption that there are two members, the positional relationship expressed as “upper” (or “lower”) in this specification may include, for example, a case in which the two members are in contact with each other and a case in which the two members are not in contact with each other and one of the two members is located above (or below) the other member. The same term may be used before and after division for each layer that is divided into a plurality of layers.

First Embodiment

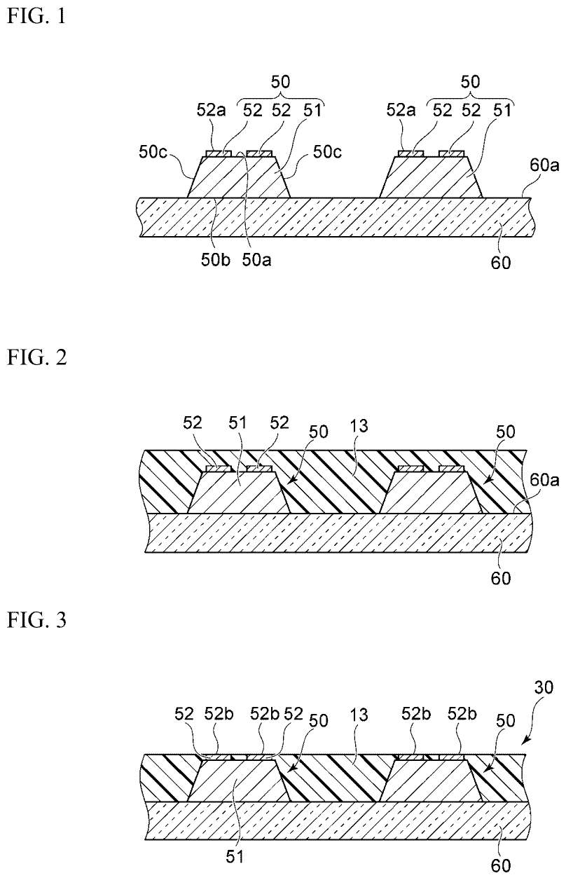

FIGS. 1 to 6 are end views illustrating a method for manufacturing a light-emitting device according to the present embodiment.

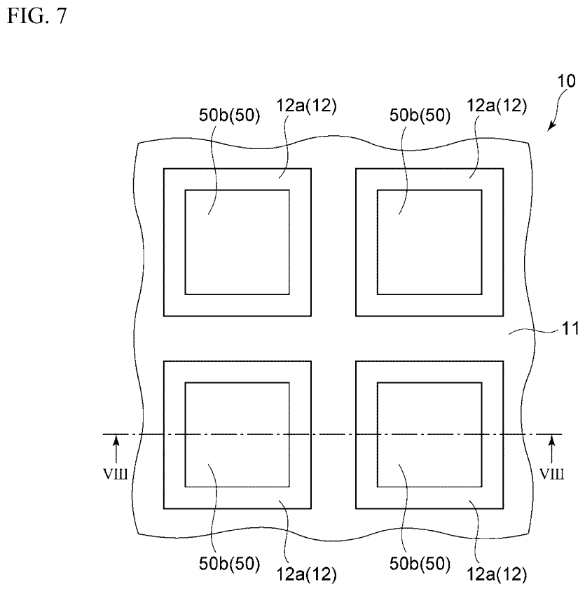

FIG. 7 is a plan view illustrating the method for manufacturing the light-emitting device according to the present embodiment.

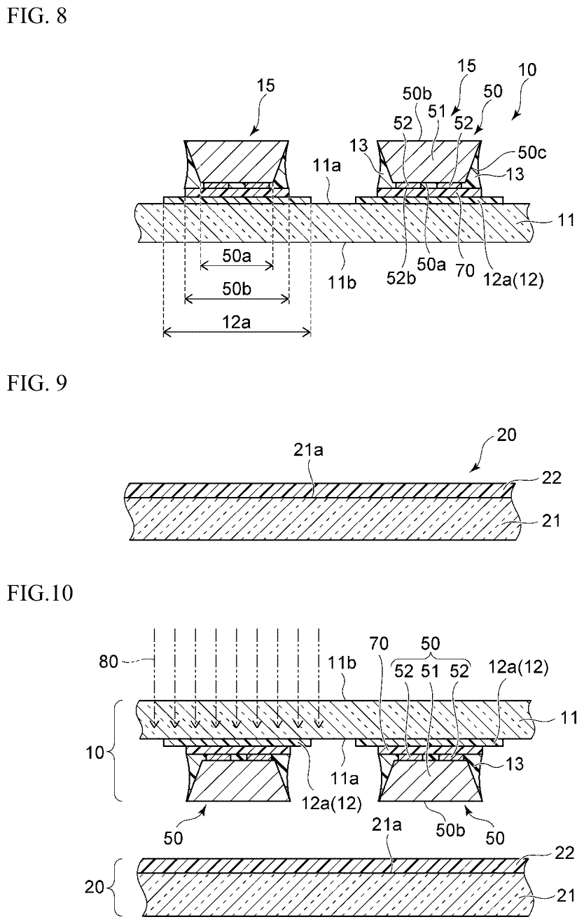

FIG. 8 is an end view taken along line VIII-VIII of FIG. 7.

FIGS. 9 to 15 are end views illustrating the method for manufacturing the light-emitting device according to the present embodiment.

A method for manufacturing a light-emitting device 1 according to a first embodiment includes a step of preparing a first structure 10, a step of preparing a second structure 20, and a step of transferring a light-emitting element 50.

Step of Preparing First Structure

The step of preparing the first structure 10 includes a step of preparing a third structure 30, a step of preparing a fourth structure 40, a step of bonding the third structure 30 and the fourth structure 40, and a step of removing a support substrate 60. The first structure 10 prepared as described above includes a first substrate 11 having a first surface 11a and a second surface 11b, a release layer 12 disposed on the first surface 11a, and one or more light-emitting elements 50 fixed to the first surface 11a side of the first substrate 11 via the release layer 12. Details of each step are described below.

First, as illustrated in FIG. 1, the support substrate 60 and the one or more light-emitting elements 50 disposed on an upper surface 60a of the support substrate 60 are prepared. The support substrate 60 is, for example, a silicon substrate or a sapphire substrate. The support substrate 60 may be a growth substrate. The support substrate 60 has the upper surface 60a and is, for example, a flat plate-shaped substrate. In a method for manufacturing portions to be the one or more light-emitting elements 50, for example, a semiconductor layered film is grown on the upper surface 60a of the support substrate 60 by a metal organic chemical vapor deposition (MOCVD) method, and electrode portions 52 are formed on the semiconductor layered film. Subsequently, part of the semiconductor layered film is removed by dry etching such as a reactive ion etching (RIE) method, or wet etching. Thus, the portions to be the one or more light-emitting elements 50 (hereinafter, also simply referred to as “light-emitting elements 50”) are manufactured. For example, the one or more light-emitting elements 50 are arranged in a matrix form along two directions orthogonal to each other in the plan view.

The light-emitting element 50 includes a semiconductor layered body 51 and the electrode portions 52. The semiconductor layered body 51 includes a nitride semiconductor such as InₓAl_{y}Ga_{1-x-y}N (0≤x, 0≤y, x+y≤1). The semiconductor layered body 51 includes a p-type layer, an n-type layer, and a light-emitting layer located between the p-type layer and the n-type layer. The light-emitting layer can have, for example, a multi-quantum well structure including a plurality of barrier layers and a plurality of well layers that are alternately layered. The electrode portions 52 include a p-side electrode connected to the p-type layer and an n-side electrode connected to the n-type layer. The electrode portion 52 has an electrode surface 52a located on a side opposite the semiconductor layered body 51.

The light-emitting element 50 has a fourth surface 50b facing the support substrate 60, a third surface 50a on a side opposite the fourth surface 50b, and fifth surfaces each connecting the third surface 50a and the fourth surface 50b. The electrode portions 52 are disposed on the third surface 50a side. The fifth surface 50c may include a recessed portion or a projected portion.

In the plan view, the fourth surface 50b is larger than the third surface 50a. In the plan view, the outer shape of the fourth surface 50b is located outside the outer shape of the third surface 50a. The plane area of the fourth surface 50b is, for example, 1.1 times to 2 times, preferably 1.1 times to 1.5 times, more preferably 1.1 times to 1.2 times the plane area of the third surface 50a. In the first embodiment, the fifth surfaces 50c are inclined with respect to the direction orthogonal to the upper surface 60a of the support substrate 60. In one example, the shape of the light-emitting element 50 is a truncated quadrangular pyramid. When the shape of the light-emitting element 50 is a truncated quadrangular pyramid, the fourth surface 50b corresponds to a lower surface of the truncated quadrangular pyramid, the third surface 50a corresponds to an upper surface of the truncated quadrangular pyramid, and the fifth surfaces 50c correspond to lateral surfaces of the truncated quadrangular pyramid.

Subsequently, as illustrated in FIG. 2, a light attenuating layer 13 is disposed on the upper surface 60a of the support substrate 60. The light attenuating layer 13 covers the semiconductor layered body 51 and the electrode portions 52. In the first embodiment, the light attenuating layer 13 covers the upper surface 60a of the support substrate 60 between adjacent light-emitting elements 50 and the third surface 50a and the fifth surfaces 50c of the light-emitting element 50, and encloses the semiconductor layered body 51 and the electrode portions 52. The light attenuating layer 13 is, for example, a resin member. The light attenuating layer 13 may be, for example, a black resin member. The light attenuating layer 13 can contain, for example, epoxy resin, acrylic resin, or polyimide resin as a main component.

Subsequently, as illustrated in FIG. 3, a portion of the light attenuating layer 13 that is located above the electrode portions 52 is removed. The portion of the light attenuating layer 13 is removed by using, for example, a grinding device. At this time, the portion of the light attenuating layer 13 is removed, the electrode portions 52 are also partially removed from the electrode surface 52a side, and new electrode surfaces 52b are formed on the electrode portions 52. By removing the portion of the light attenuating layer 13 that is located above the electrode portions 52, the electrode surfaces 52b of the electrode portions 52 are exposed from the light attenuating layer 13. In the first embodiment, the electrode surface 52b of the electrode portion 52, an upper surface of the light attenuating layer 13 located in between the electrode surfaces 52b of each light-emitting element 50, and an upper surface of the light attenuating layer 13 located in between the adjacent light-emitting elements 50 are flush with one another. In this way, the third structure 30 is prepared.

The third structure 30 includes the support substrate 60, the one or more light-emitting elements 50 disposed on the support substrate 60, and the light attenuating layer 13.

The light attenuating layer 13 surrounds and holds each light-emitting element 50. The light attenuating layer 13 is located in between the electrode portions 52 of each light-emitting element 50 and in between adjacent light-emitting elements 50. The light attenuating layer 13 has a role of suppressing separation of the light-emitting elements 50 and fixing the positions of the light-emitting elements 50 when the support substrate 60 is removed in a subsequent step. The electrode surfaces 52b of the electrode portions 52 are exposed from the light attenuating layer 13.

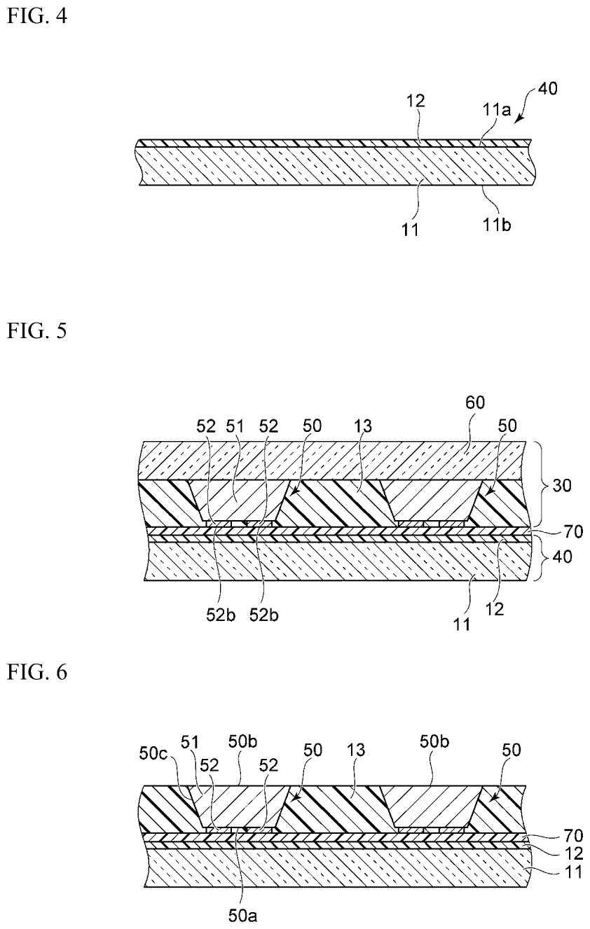

Subsequently, as illustrated in FIG. 4, the fourth structure 40 is prepared. The step of preparing the fourth structure 40 may be performed before, after, or at the same time as the step of preparing the third structure 30. The fourth structure 40 includes the first substrate 11 and the release layer 12. The first substrate 11 is a substrate that can transmit laser light 80 to be described below, and is, for example, a sapphire substrate. The first substrate 11 has the first surface 11a and the second surface 11b located on a side opposite the first surface 11a. The release layer 12 is disposed on the first surface 11a of the first substrate 11. The release layer 12 is, for example, a member that can absorb the laser light 80 to be described below and can be removed by laser ablation, and is, for example, a photosensitive resin.

Subsequently, as illustrated in FIG. 5, in a state in which the electrode surfaces 52b of the electrode portions 52 in the third structure 30 and the release layer 12 in the fourth structure 40 are opposed to each other, the electrode surfaces 52b of the electrode portions 52 and the release layer 12 are bonded to each other via an adhesive layer 70. An upper surface of the adhesive layer 70 is in contact with the electrode surfaces 52b of the electrode portions 52 of the third structure 30, the light attenuating layer 13 located in between the electrode portions 52 of each light-emitting element 50, and the light attenuating layer 13 located in between the adjacent light-emitting elements 50. A lower surface of the adhesive layer 70 is in contact with an upper surface of the release layer 12.

The adhesive layer 70 is, for example, a sheet-shaped member. In a state immediately before the third structure 30 and the fourth structure 40 are bonded to each other, the adhesive layer 70 may be disposed on the third structure 30 side or may be disposed on the fourth structure 40 side. The adhesive layer 70 may be formed using a known member. Examples of the adhesive layer 70 contain, as main components, a thermosetting resin such as silicone resin, silicone-modified resin, epoxy resin, and phenol resin, and a thermoplastic resin such as polycarbonate resin, acrylic resin, methylpentene resin, and polynorbornene resin.

Subsequently, as illustrated in FIG. 6, the support substrate 60 is removed. The support substrate 60 can be removed by, for example, a laser lift off (LLO) method, grinding, polishing, etching, or the like. Thus, the fourth surfaces 50b of the light-emitting elements 50 and the light attenuating layer 13 between the light-emitting elements 50 are exposed to the outside from the surface from which the support substrate 60 has been removed.

Subsequently, as illustrated in FIGS. 7 and 8, the light attenuating layer 13, the adhesive layer 70, and the release layer 12 are selectively removed for separation for each light-emitting element 50. The selective removal of the light attenuating layer 13 and the like is performed by etching such as a chemical mechanical polishing (CMP) method or an RIE method. In the first embodiment, the light attenuating layer 13, the adhesive layer 70, and the release layer 12 are divided between the adjacent light-emitting elements 50. Thus, the upper surface 11a of the first substrate 11 is exposed to the outside between the adjacent light-emitting elements 50. In a plurality of separated layers 12a, each layer 12a is disposed forming a pair with the light-emitting element 50. In this way, the first structure 10 is prepared. In the first structure 10, the release layer 12 is a collective term for the plurality of layers 12a.

The first structure 10 includes the first substrate 11 and a plurality of structures The first substrate 11 has the first surface 11a and the second surface 11b located on a side opposite the first surface 11a. The plurality of structures 15 are disposed on the first surface 11a of the first substrate 11. The structure 15 includes the layer 12a of the release layer 12, the adhesive layer 70, and the light-emitting element 50 in this order from the first surface 11a side of the first substrate 11, and includes the light attenuating layer 13 surrounding the light-emitting element 50. The release layer 12 is disposed on the first surface 11a of the first substrate 11. The light-emitting element 50 is fixed to the first surface 11a side of the first substrate 11 via the adhesive layer 70 and the layer 12a of the release layer 12. The light attenuating layer 13 is disposed between the adhesive layer 70 and the light-emitting element 50. The light attenuating layer 13 covers the third surface 50a and the fifth surface 50c of the light-emitting element 50, but does not cover the fourth surface 50b. The adhesive layer 70 is disposed between the release layer 12 and the light attenuating layer 13 and between the release layer 12 and the light-emitting element 50.

The light-emitting element 50 has the third surface 50a facing the release layer 12, the fourth surface 50b on a side opposite the third surface 50a, and the fifth surface 50c connecting the third surface 50a and the fourth surface 50c. The electrode portions 52 are disposed on the third surface 50a side of the light-emitting element 50, and the electrode surfaces 52b of the electrode portions 52 are in contact with the adhesive layer 70. In the plan view, the fourth surface 50b is larger than the third surface 50a. In the plan view, each layer 12a of the release layer 12 encloses the fourth surface 50b of the light-emitting element 50.

Step of Preparing Second Structure

Subsequently, as illustrated in FIG. 9, the second structure 20 is prepared. The step of preparing the second structure 20 may be performed before, after, or at the same time as the step of preparing the first structure 10. The second structure 20 includes a second substrate 21 and an adhesive layer 22. The second substrate 21 is, for example, a glass substrate. The second substrate 21 has an upper surface 21a, and the adhesive layer 22 is disposed on the upper surface 21a of the second substrate 21. As the adhesive layer 22, for example, a resin member containing silicone-based resin or acrylic-based resin as a base material can be used.

Step of Transferring Light-Emitting Element

Subsequently, as illustrated in FIG. 10, the first structure 10 is opposed to the second structure 20. Specifically, the first surface 11a of the first substrate 11 and the upper surface 21a of the second substrate 21 are opposed to each other such that the light-emitting elements 50 are disposed between the first substrate 11 and the second substrate 21. In this case, the first structure 10 is spaced apart from the second structure 20. That is, the light-emitting element 50 is spaced apart from the adhesive layer 22.

In this state, the release layer 12 is irradiated with the laser light 80 from the second surface 11b side of the first substrate 11. The laser light 80 is light that can pass through the first substrate 11 and remove the release layer 12. The irradiation with the laser light 80 is performed using, for example, a medium- and long-wavelength laser. The laser light 80 is, for example, light having a light emission peak wavelength in a wavelength range from 150 nm to 1600 nm, preferably light having a light emission peak wavelength in a wavelength range from 150 nm to 600 nm, more preferably light having a light emission peak wavelength in a wavelength range from 250 nm to 400 nm. The laser light 80 passes through the first substrate 11 in the direction from the second surface 11b of the first substrate 11 toward the first surface 11a, and reaches the release layer 12. For example, in one irradiation, only one layer 12a is irradiated with the laser light 80. In one irradiation, two or more layers 12a may be irradiated with the laser light 80, or all the layers 12a may be irradiated with the laser light 80. Each layer 12a may be irradiated with the laser light 80 twice or more.

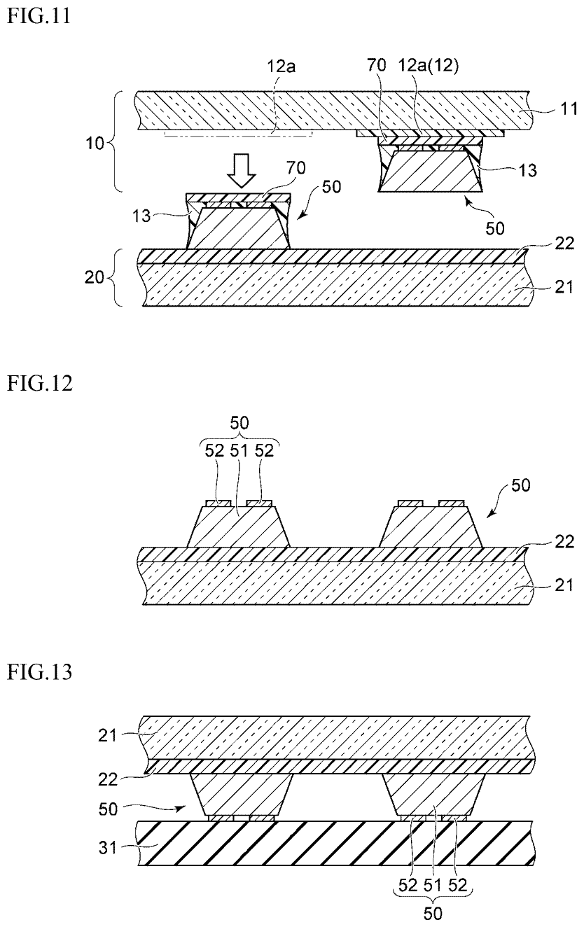

Thus, as illustrated in FIG. 11, the layer 12a of the release layer 12 irradiated with the laser light 80 is removed. The removal in this case includes, for example, a case in which the layer 12a of the release layer 12 is sublimated and disappears. When the layer 12a is sublimated and removed, the light-emitting element 50 is separated from the first substrate 11, and is biased toward the second substrate 21 due to volume expansion of the layer 12a caused by the sublimation. As a result, the light-emitting element 50 is transferred from the first substrate 11 to the second substrate 21. When the first substrate 11 is disposed above the second substrate 21, the light-emitting element 50 is also biased toward the second substrate 21 by gravity. As long as the light-emitting element 50 is transferred, the layer 12a of the release layer 12 may be entirely removed or may be partially removed. In addition to the release layer 12, at least part of the adhesive layer 70 disposed below the release layer 12 may be removed by the laser light 80.

The light-emitting element 50 separated from the first substrate 11 reaches the adhesive layer 22 of the second structure 20 and is bonded to the second substrate 21 via the adhesive layer 22. Subsequently, the plurality of light-emitting elements 50 are sequentially transferred from the first substrate 11 to the second substrate 21 by repeatedly irradiating the other layers 12a of the release layer 12 with the laser light 80. In this way, the one or more light-emitting elements 50 are transferred from the first substrate 11 to the second substrate 21. At least part of the light attenuating layer 13 and the adhesive layer 70 remains on the light-emitting element 50.

Subsequently, as illustrated in FIG. 12, the light attenuating layer 13 is removed. An example of a method for removing the light attenuating layer 13 includes an etching method such as an RIE method. By removing the light attenuating layer 13, the adhesive layer 70 disposed on the light attenuating layer 13 is also removed at the same time. After the light attenuating layer 13 is removed by an RIE method, a cleaning process may be performed using pure water or the like.

Subsequently, as illustrated in FIG. 13, the light-emitting elements 50 disposed on the second substrate 21 are disposed on a wiring substrate 31. Specifically, the wiring substrate 31 provided with a wiring line on the upper surface thereof is prepared, and the light-emitting elements 50 are disposed on the upper surface of the wiring substrate 31 in a state in which the electrode portions 52 of the light-emitting elements 50 face downward. The electrode portions 52 of the light-emitting elements 50 and the wiring line on the wiring substrate 31 are electrically connected to each other. The electrode portions 52 of the light-emitting elements 50 and the wiring line on the wiring substrate 31 are electrically connected to each other via, for example, a joining member. The joining member is made of, for example, gold or copper.

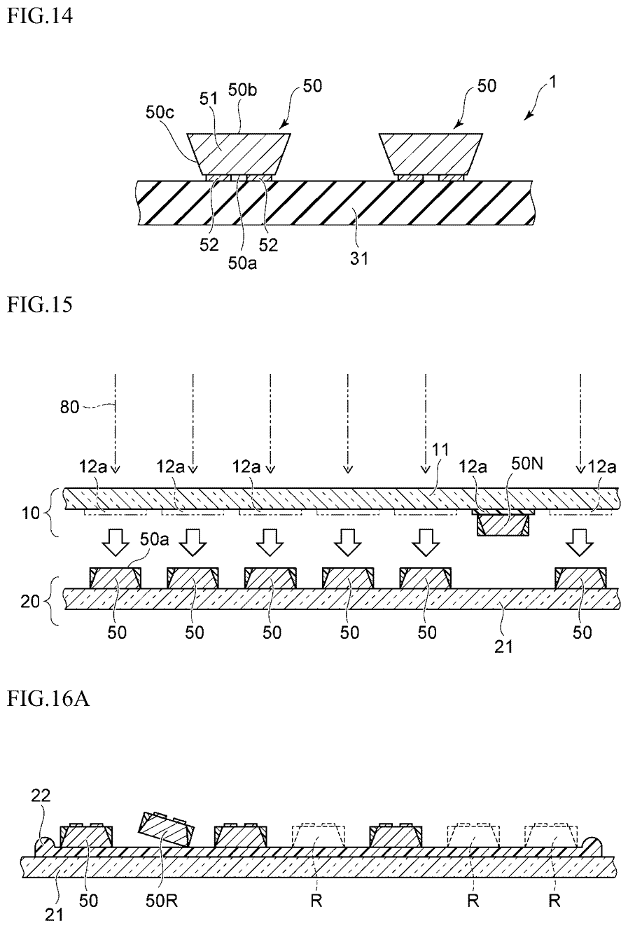

Subsequently, as illustrated in FIG. 14, the second substrate 21 is removed together with the adhesive layer 22. In this way, the light-emitting device 1 according to the present embodiment is manufactured. The light-emitting device 1 may include a phosphor member containing a phosphor that converts the wavelength of at least part of light from the light-emitting element 50, or a resin member surrounding the light-emitting element 50 and having high light reflectivity, as in a second embodiment to be described below.

The first structure 10, the second structure 20, the third structure 30, and the fourth structure 40 may be prepared by the above manufacture, or may be prepared by purchase or the like.

As illustrated in FIG. 15, in the laser light 80 irradiating step, some of the light-emitting elements 50 may be irradiated with no laser light. Specifically, the step of manufacturing the light-emitting device 1 may include a step of inspecting each of the light-emitting elements 50 and detecting a defective light-emitting element 50N by the inspection in the step of preparing the first structure 10, and a step of irradiating the layers 12a, other than the layer 12a of the release layer 12 corresponding to the light-emitting element 50N determined to be defective by the inspection, with the laser light 80 in the step of transferring one or more light-emitting elements. The inspection may be an appearance inspection for inspecting the appearance of the light-emitting element 50 or an electrical characteristic evaluation for evaluating the electrical characteristics of the light-emitting element 50. Thus, the defective light-emitting element 50N is not transferred, and only non-defective light-emitting elements 50 can be transferred. In this way, because the light-emitting element 50N determined to be defective in the appearance inspection or the like can be removed, only non-defective light-emitting elements 50 can be used in a subsequent step. Similarly, non-defective light-emitting elements 50 may be detected by inspection, and the layers 12a of the release layer 12 corresponding to the non-defective light-emitting elements 50 may be irradiated with the laser light 80 to transfer only the non-defective light-emitting elements 50.

The step of manufacturing the light-emitting device 1 may further include a rework process after the step of transferring the one or more light-emitting elements 50. The rework process includes a step of inspecting the transfer state of the light-emitting elements on the second substrate 21 after the transfer and detecting a light-emitting element 50R in a defective transfer state or a region R in which no light-emitting element 50 is disposed, a step of, when there is the light-emitting element 50R in a defective transfer state, removing the light-emitting element 50R, and a step of disposing a new light-emitting element 50 in a region in which the removed light-emitting element 50R had been disposed or the region R in which no light-emitting element 50 is disposed.

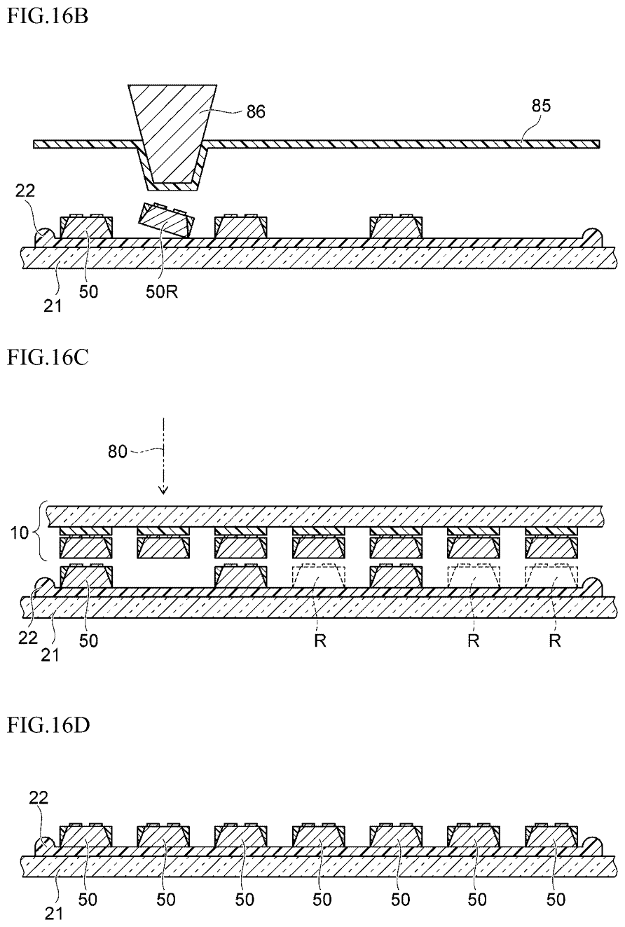

FIGS. 16A to 16D are end views illustrating a rework process after the light-emitting elements are transferred.

Specifically, as illustrated in FIG. 16A, the transfer state of the light-emitting elements 50 on the second substrate 21 after the transfer is inspected, and the light-emitting element 50R in a defective transfer state or a region R in which no light-emitting element 50 is disposed is detected. The light-emitting element 50R in a defective transfer state may be a light-emitting element whose position after the transfer is shifted from a reference position in any direction. The region R is a region in which the light-emitting element 50 is supposed to be disposed, but is a region in which no light-emitting element 50 is actually disposed. First, the light-emitting element 50R in a defective transfer state and the region R are detected by appearance inspection.

Subsequently, when the light-emitting elements 50 include the light-emitting element 50R in a defective transfer state, the light-emitting element 50R in a defective transfer state is removed as illustrated in FIG. 16B. In a method for removing the light-emitting element 50R, for example, a pressing portion 86 is pressed against the light-emitting element 50R via an adhesive sheet 85, whereby the light-emitting element 50R is bonded to the adhesive sheet 85. Subsequently, the pressing portion 86 and the adhesive sheet 85 are separated from the second substrate 21. Thus, the light-emitting element 50R is removed from the second substrate 21 together with the adhesive sheet 85.

Subsequently, as illustrated in 16C, a new light-emitting element 50 is disposed in the region in which the removed light-emitting element 50R had been disposed or in the region R. In a method for disposing the new light-emitting element 50, for example, the first structure 10 including the new light-emitting element 50 is prepared, and the light-emitting element 50 corresponding to the region in which the light-emitting element 50R had been disposed or the region R is irradiated with the laser light 80 to transfer the light-emitting element 50 again. Thus, as illustrated in FIG. 16D, non-defective light-emitting elements 50 are disposed in all the regions on the second substrate 21 in which the light-emitting elements 50 are to be disposed.

An effect of the present embodiment is described below. In the light-emitting device 1 according to the present embodiment, the fourth surface 50b of the light-emitting element 50 is larger than the third surface 50a. The fifth surfaces 50c are inclined with respect to the third surface 50a and spread in a direction from the third surface 50a toward the fourth surface 50b. Thus, light from the light-emitting layer of the light-emitting element 50 is efficiently reflected by the fifth surfaces 50c, and is easily directed to the fourth surface 50b which is a light-emitting surface. As a result, the light extraction efficiency of the light-emitting device 1 is increased.

In the laser light irradiating step, the layer 12a of the release layer 12 encloses the fourth surface 50b of the light-emitting element 50 in the plan view. Therefore, the light-emitting element 50 is not directly irradiated with the laser light 80 until the layer 12a is removed. This can suppress damage to the light-emitting element 50 due to the laser light 80. As a result, the reliability of the light-emitting device 1 is improved.

In the present embodiment, because the light attenuating layer 13 covers the third surface 50a and the fifth surfaces 50c of the light-emitting element 50 in the laser light 80 irradiating step, part of the laser light 80 transmitted through the layer 12a is absorbed by the light attenuating layer 13. As a result, the amount of the laser light 80 that reaches the light-emitting element 50 is reduced, so that damage to the light-emitting element 50 can be suppressed. This also improves the reliability of the light-emitting device 1.

First Modified Example of First Embodiment

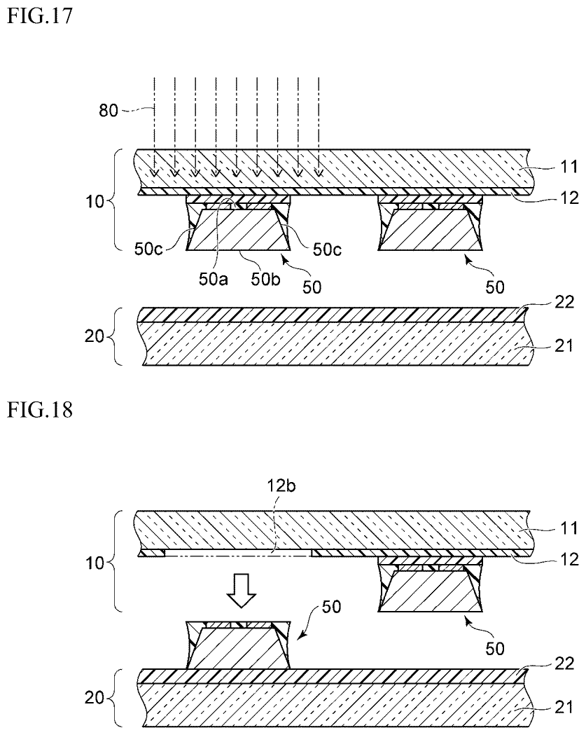

FIGS. 17 and 18 are end views illustrating a method for manufacturing a light-emitting device according to the present modified example.

The present modified example is different from the first embodiment in that the release layer 12 is one continuous layer. In the present modified example, in the first structure 10, the release layer 12 is not divided into a plurality of layers 12a, and is one continuous layer.

The release layer 12 in the present modified example is formed by etching the light attenuating layer 13 and the adhesive layer 70 such that the release layer 12 is not completely divided in the steps illustrated in FIGS. 7 and 8, for example. The release layer 12 is a continuous layer, and part of the release layer 12 in the thickness direction may be removed by etching or the like. In this case, the release layer 12 encloses all the fourth surfaces 50b of the plurality of light-emitting elements 50 included in the first structure 10 in a plan view.

Subsequently, a portion 12b of the release layer 12 corresponding to one light-emitting element 50 is irradiated with the laser light 80. Thus, as illustrated in FIG. 18, the portion 12b of the release layer 12 is sublimated, and the light-emitting element 50 is transferred from the first substrate 11 to the second substrate 21. The manufacturing method, configuration, and effects other than those described above in the present modified example are similar to those in the first embodiment. Second Modified Example of First Embodiment

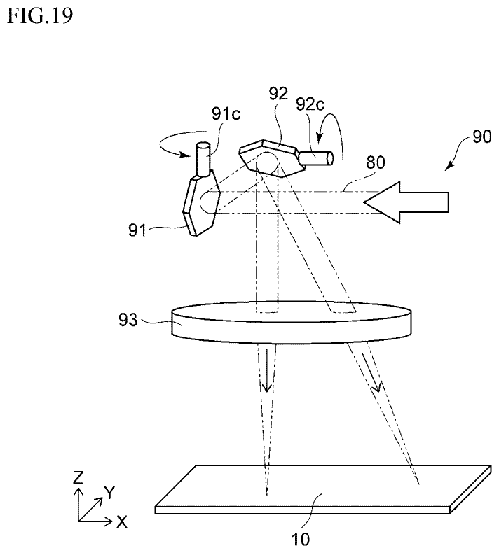

FIG. 19 is a view illustrating a Galvano laser device used in the present modified example.

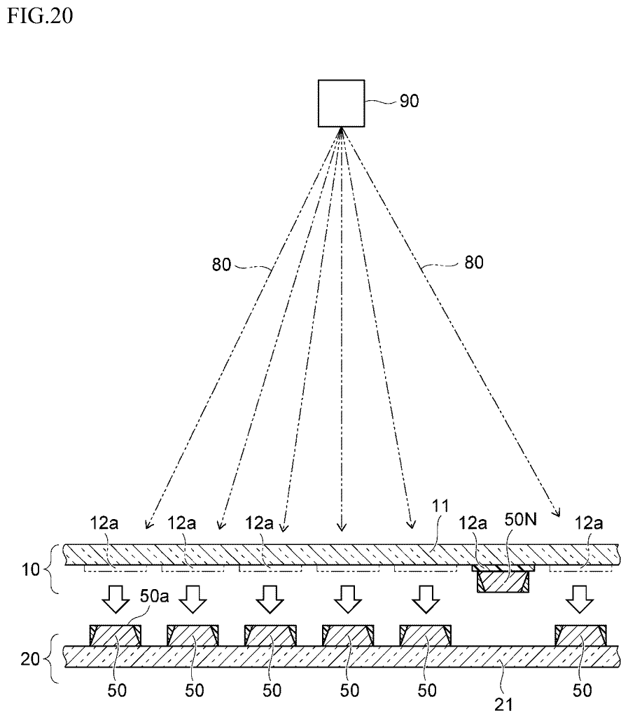

FIG. 20 is an end view illustrating a method for manufacturing a light-emitting device according to the present modified example.

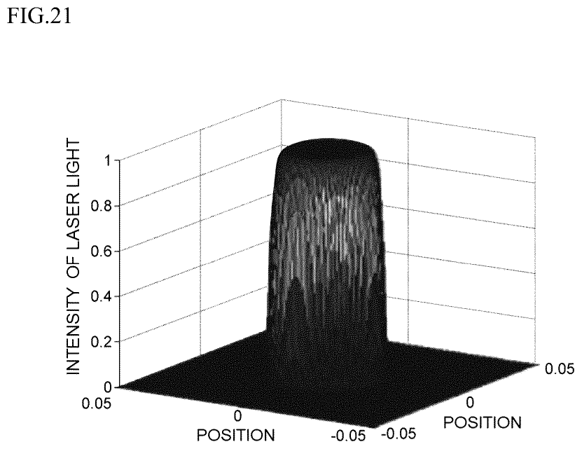

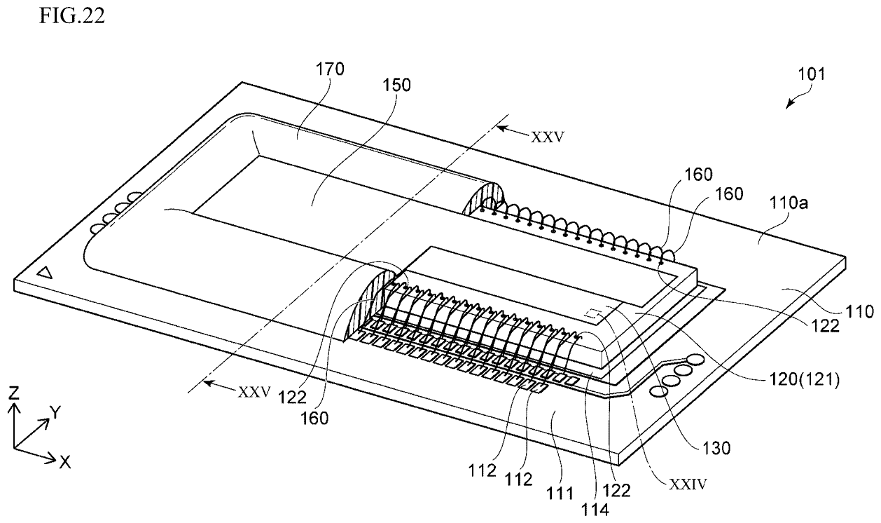

FIG. 21 is a view illustrating an intensity distribution of laser light.

The present modified example is different from the first embodiment in that a Galvano laser device is used in the laser light 80 irradiating step. Specifically, in the laser light 80 irradiating step, portions of the release layer 12 corresponding to the plurality of light-emitting elements 50 are irradiated with the laser light 80 while the emission direction of the laser light 80 is controlled by a Galvano method.

As illustrated in FIG. 19, a Galvano laser irradiation device 90 is provided with, for example, two Galvano mirrors 91 and 92 and a lens 93. A direction in which the laser light 80 is incident when viewed from the laser irradiation device 90 is referred to as an “X direction,” a direction from the upper surface of the first structure 10 toward the lens 93 is referred to as a “Z direction,” and a direction orthogonal to the X direction and the Z direction is referred to as a “Y direction.”

The Galvano mirror 91 is rotatable at an arbitrary angle about a rotating shaft 91c extending in the Z direction. The Galvano mirror 92 is rotatable at an arbitrary angle about a rotating shaft 92c extending in the X direction. The lens 93 is disposed at a position on which laser light emitted from the Galvano mirror 92 is incident.

The laser light 80 is incident on the Galvano mirror 91 from the X direction. The Galvano mirror 91 controls the reflection direction of the laser light 80 in the Y direction. The laser light 80 reflected by the Galvano mirror 91 is incident on the Galvano mirror 92. The Galvano mirror 92 controls the reflection direction of the laser light 80 in the X direction. The laser light 80 reflected by the Galvano mirror 92 is condensed at an irradiation target position by the lens 93. In the present modified example, the first structure 10 is disposed at the irradiation target position.

As illustrated in FIG. 20, portions of the release layer 12 corresponding to the light-emitting elements 50, for example, the layers 12a, are sequentially irradiated with the laser light 80 emitted from the Galvano laser irradiation device 90. Thus, the layers 12a are removed, and the light-emitting elements 50 are transferred from the first structure 10 to the second structure 20.

When the Galvano laser irradiation device 90 is used, the laser light 80 is emitted obliquely to the third surface 50a of the light-emitting element 50 disposed on an end side of a region that can be irradiated with the laser light 80. In this case, the fifth surfaces 50c of the light-emitting element 50 are easily irradiated with the laser light 80. However, in the method for manufacturing the light-emitting device of the present disclosure, the light attenuating layer 13 is disposed on the fifth surfaces 50c, so that the light attenuating layer 13 can effectively absorb the obliquely emitted laser light 80. This can suppress damage to the light-emitting element 50 due to the laser light 80.

As in the first embodiment, when a defective light-emitting element 50N is detected in the first structure 10, only the layers 12a of the release layer 12 corresponding to non-defective light-emitting elements 50 may be irradiated with the laser light 80. In the Galvano laser irradiation device 90, an irradiation target can be selected and subjected to irradiation, so that it is possible to efficiently and selectively irradiate the non-defective light-emitting elements 50. In the Galvano laser irradiation device 90, it is possible to irradiate an arbitrary light-emitting element with laser light by changing angles of the two Galvano mirrors, so that it is possible to shorten the time required for laser light irradiation as compared with, for example, a laser irradiation device that emits laser light while moving a nozzle.

As in the first embodiment, the manufacturing method may further include a rework process after the step of transferring one or more light-emitting elements 50. Also in the step of disposing a new light-emitting element 50 in the rework process, the light-emitting element 50 can be selectively transferred using the Galvano laser irradiation device 90.

As illustrated in FIG. 21, an intensity distribution of the laser light 80 is preferably a top hat distribution. This stabilizes the process of sublimation of the release layer 12 and improves the precision of transfer of the light-emitting element 50. For example, it is possible to improve the precision of the transfer position of the light-emitting element 50 on the second substrate 21, and to suppress the inclination of the light-emitting element 50 when the light-emitting element 50 reaches the second substrate 21. The manufacturing method, configuration, and effects other than those described above in the present modified example are similar to those in the first embodiment.

Second Embodiment

A second embodiment is a specific example of the method for manufacturing the light-emitting device according to the first embodiment described above.

The configuration of a light-emitting device according to the present embodiment is first described.

FIG. 22 is a perspective view schematically illustrating the light-emitting device according to the present embodiment when viewed from obliquely above.

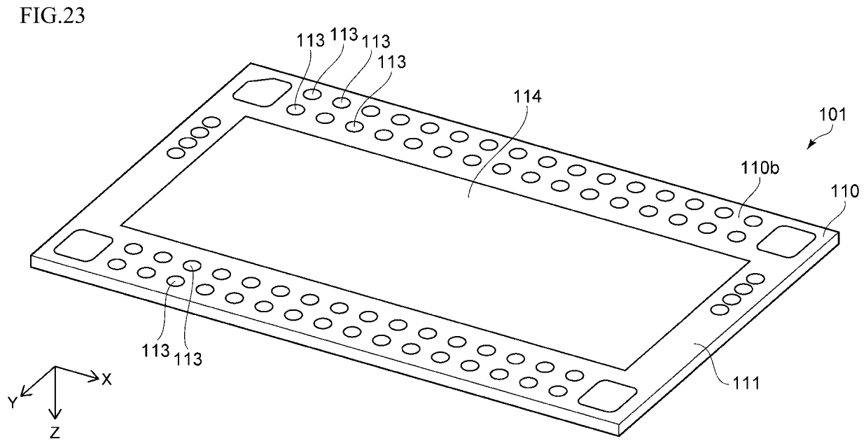

FIG. 23 is a perspective view schematically illustrating the light-emitting device according to the present embodiment when viewed from obliquely below.

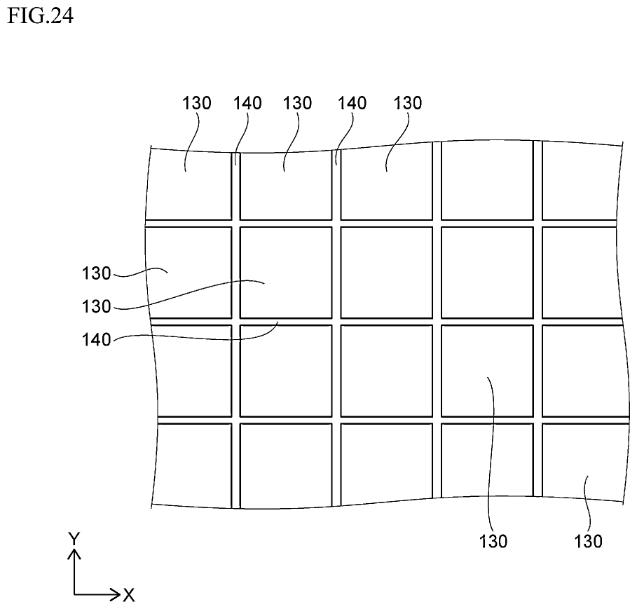

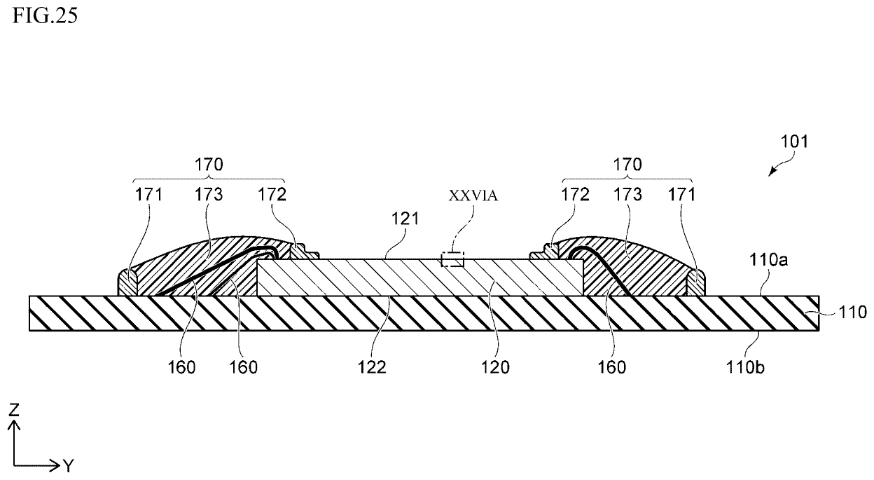

FIG. 24 is a partially enlarged top view illustrating a region XXIV of FIG. 22.

FIG. 25 is a cross-sectional view taken along line XXV-XXV of FIG. 22.

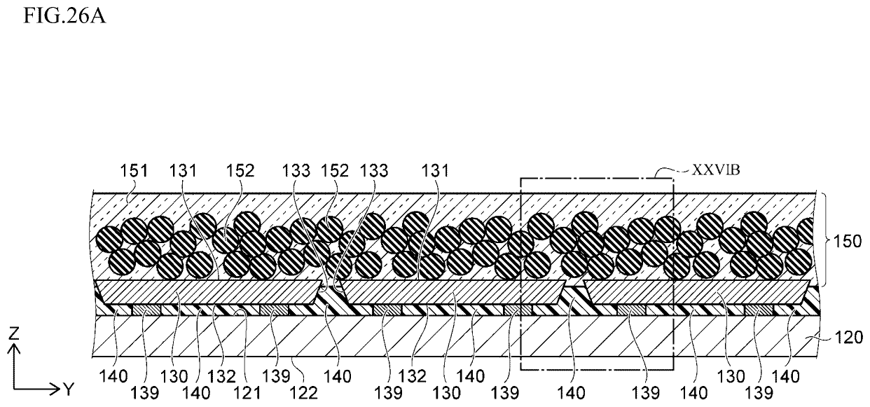

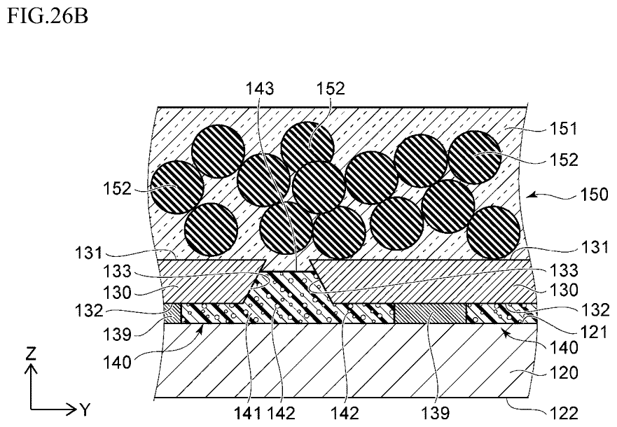

FIG. 26A is a partially enlarged cross-sectional view illustrating a region XXVIA of FIG. 25.

FIG. 26B is a partially enlarged cross-sectional view illustrating a region XXVIB of FIG. 26A.

In the present embodiment, XYZ orthogonal coordinates are employed for convenience of explanation. A longer direction of a package substrate 110 is referred to as an “X direction,” a shorter direction thereof is referred to as a “Y direction,” and a thickness direction thereof is referred to as a “Z direction.” In the “Z direction,” a direction from a lower surface 110b to an upper surface 110a of the package substrate 110 is also referred to as an “upper” direction, and an opposite direction thereof is also referred to as a “lower” direction, but these expressions are also for convenience and are independent of the direction of gravity.

As illustrated in FIGS. 22 to 24, a light-emitting device 101 according to the present embodiment includes the package substrate 110, a wiring substrate 120 disposed on the upper surface of the package substrate 110, a plurality of light-emitting elements 130 disposed on an upper surface of the wiring substrate 120, a light reflective member 140 disposed between the light-emitting elements 130 and covering lateral surfaces of the light-emitting elements 130, a wavelength conversion member 150 disposed above the plurality of light-emitting elements 130, a plurality of wires 160 electrically connecting the package substrate 110 and the wiring substrate 120, and a covering member 170 covering the wires 160. For convenience of illustration, FIG. 22 does not illustrate part of the covering member 170 and part of the wavelength conversion member 150, and visualizes some of the wires 160 and some of the light-emitting elements 130.

The package substrate 110 has, for example, a rectangular shape in a plan view. The package substrate 110 includes an insulating base 111 made of, for example, a ceramic or a resin as a base material. The package substrate 110 is provided with a plurality of first pads 112 on the upper surface 110a of the package substrate 110 and a plurality of second pads 113 on the lower surface 110b thereof. The first pad 112 and the second pad 113 are electrically connected to each other by a conductive via or the like made of copper (Cu) or the like disposed inside the insulating base 111.

A heat dissipation member 114 made of copper, for example, is exposed on the upper surface 110a and the lower surface 110b of the package substrate 110. As the heat dissipation member 114, for example, a material having excellent thermal conductivity such as aluminum or copper can be used. In the plan view, the heat dissipation member 114 is disposed in the central portion of the package substrate 110. The first pads 112 and the second pads 113 are disposed on both sides of the heat dissipation member 114 in the Y direction. The first pads 112 and the second pads 113 are arranged along long sides of the package substrate 110, for example.

The wiring substrate 120 is disposed on the heat dissipation member 114 of the package substrate 110. The wiring substrate 120 is, for example, a silicon substrate incorporating an integrated circuit, such as an application specific integrated circuit (ASIC) substrate. A lower surface of the wiring substrate 120 is joined to an upper surface of the heat dissipation member 114 via, for example, a joining member. As the joining member, for example, a silicone silver paste is used. Electrodes corresponding to the respective light-emitting elements 130 are disposed in the central portion of an upper surface 121 of the wiring substrate 120. External connection pads 122 are disposed on the outer peripheral portion of the upper surface 121 of the wiring substrate 120.

The wires 160 are connected to the first pads 112 of the package substrate 110 and the external connection pads 122 of the wiring substrate 120. The wire 160 is made of, for example, gold (Au). For example, the number of the wires 160 is the same as the number of the first pads 112 and the number of the external connection pads 122.

In the plan view, the covering member 170 has a frame shape along an outer edge of the wiring substrate 120. The covering member 170 is disposed on the upper surface of the package substrate 110 and the upper surface of the wiring substrate 120, and covers the first pads 112 of the package substrate 110, the wires 160, and the external connection pads 122 of the wiring substrate 120. In the plan view, the covering member 170 has a frame shape with an opening in the central portion thereof, and the wavelength conversion member 150 is exposed through the opening of the covering member 170.

As illustrated in FIG. 25, the covering member 170 includes a first resin frame 171 constituting an outer frame of the covering member 170, a second resin frame 172 constituting an inner frame of the covering member 170, and a protective resin portion 173 disposed between the first resin frame 171 and the second resin frame 172. The first resin frame 171 is disposed on the package substrate 110. The second resin frame 172 is disposed on the wiring substrate 120. The protective resin portion 173 continuously covers the upper surface of the package substrate 110, the upper surface of the wiring substrate 120, and the surfaces of the wires 160. The first resin frame 171 and the second resin frame 172 are made of, for example, a light-transmissive resin. The protective resin portion 173 is made of, for example, a light-transmissive resin, as a base material, containing a light reflective material. As a light-transmissive resin, for example, dimethyl silicone resin can be used. A light reflective material is, for example, aluminum oxide.

As illustrated in FIGS. 22, 24, and 25, the plurality of light-emitting elements 130 are disposed on the central portion of the upper surface 121 of the wiring substrate 120. The plurality of light-emitting elements 130 are arranged in a matrix form, for example. In an example, there are four segments in each of which the light-emitting elements 130 are disposed in 64 rows and 64 columns; thus, a total of 16384 light-emitting elements 130 are disposed. In an example, the size of each light-emitting element 130 is in a range from 40 μm to 50 μm. In an example, the distance between the adjacent light-emitting elements 130 is in a range from 4 μm to 8 μm. The light-emitting elements 130 are connected to the electrodes exposed on the upper surface 121 of the wiring substrate 120. The light-emitting element 130 is, for example, a light-emitting diode and emits, for example, blue light.

As illustrated in FIG. 26A, the light-emitting element 130 has an upper surface 131, a lower surface 132 on the side opposite the upper surface 131, and lateral surfaces 133 between the upper surface 131 and the lower surface 132. The upper surface 131 corresponds to the fourth surface, the lower surface 132 corresponds to the third surface, and the lateral surface 133 corresponds to the fifth surface. The lateral surfaces 133 are inclined such that they spread from the lower surface 132 toward the upper surface 131. The lateral surfaces 133 are disposed on four sides. The lower surface 132 of the light-emitting element 130 faces the upper surface 121 of the wiring substrate 120. The light-emitting element 130 is connected to the electrodes of the wiring substrate 120 through joining members 139. Therefore, the lower surface 132 of the light-emitting element 130 is away from the upper surface 121 of the wiring substrate 120. The joining member 139 is made of, for example, gold or copper.

The light reflective member 140 is disposed between the upper surface 121 of the wiring substrate 120 and the lower surface 132 of the light-emitting element 130, and between the lateral surfaces 133 of the adjacent light-emitting elements 130. In the light reflective member 140, a base material 141 includes light reflective materials 142. The concentration of the light reflective materials 142 in the light reflective member 140 is preferably in a range from 50 mass % to 70 mass % and is, for example, 60 mass %. The base material 141 is, for example, dimethyl silicone resin. The light reflective material 142 is, for example, titanium oxide.

The wavelength conversion member 150 covers the upper surface 131 of the light-emitting element 130 and an upper surface 143 of the light reflective member 140. The wavelength conversion member 150 is in contact with the upper surface 131 of the light-emitting element 130, an upper portion of the lateral surface 133, and the upper surface 143 of the light reflective member 140. In the wavelength conversion member 150, a base material 151 includes phosphors 152. The base material 151 is, for example, dimethyl silicone resin. The phosphor 152 contains, for example, yttrium aluminum garnet (YAG), absorbs blue light from the light-emitting element 130, and emits yellow light.

As illustrated in FIG. 26B, between the adjacent light-emitting elements 130, the upper surface 143 of the light reflective member 140 is located between the upper surface 131 and the lower surface 132 of the light-emitting element 130 in the Z direction, that is, in the direction from the wiring substrate 120 toward the wavelength conversion member 150. Thus, a lower portion of the lateral surface 133 of the light-emitting element 130 is covered by the light reflective member 140, and an upper portion thereof is covered by the wavelength conversion member 150.

A method for manufacturing a light-emitting device according to the second embodiment is described below.

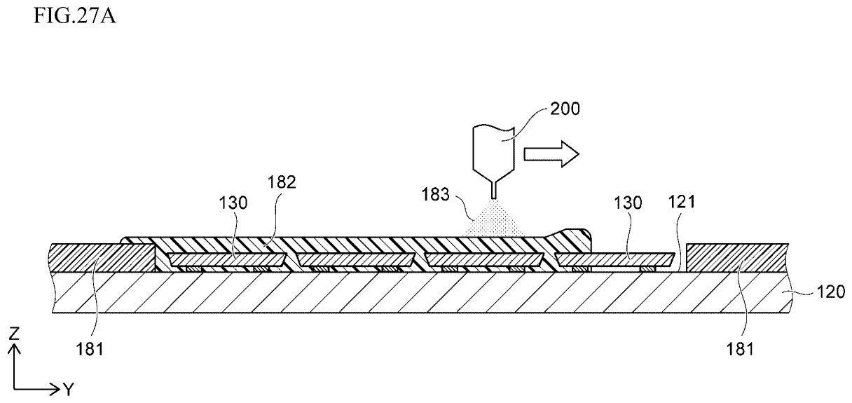

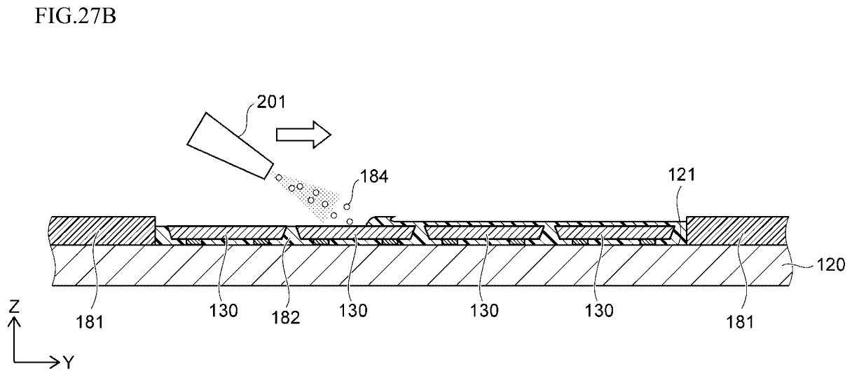

FIGS. 27A and 27B are end views illustrating the method for manufacturing the light-emitting device according to the present embodiment.

The method for manufacturing the light-emitting device according to the present embodiment includes an element preparation step of preparing one or more light-emitting elements 130 disposed on the upper surface of the wiring substrate 120, a light reflective member disposing step of covering the lateral surfaces of the light-emitting elements 130 with the light reflective member 140, a substrate disposing step of disposing the wiring substrate 120 on the upper surface of the package substrate 110, a wire connection step of electrically connecting the first pads 112 of the package substrate 110 and the external connection pads 122 of the wiring substrate 120 with the wires 160, a wavelength conversion member disposing step of disposing the wavelength conversion member 150 on the plurality of light-emitting elements 130, and a covering member disposing step of disposing the covering member 170 that covers the wires 160.

Element Preparation Step

Because the element preparation step is the same as that of the first embodiment, the element preparation step is described with reference to the drawings of the first embodiment. First, as illustrated in FIG. 1, the plurality of light-emitting elements 130 (light-emitting elements 50 in the first embodiment) are formed on the support substrate 60.

Subsequently, the first structure 10 including the light-emitting elements 130 is manufactured through the steps illustrated in FIGS. 2 to 8. At this time, in the plan view, the upper surface 131 (fourth surface) of the light-emitting element 130 is larger than the lower surface 132 (third surface) thereof, and the release layer 12 encloses the upper surface 131 of the light-emitting element 130. On the other hand, as illustrated in FIG. 9, the second structure 20 including the second substrate 21 is manufactured.

Subsequently, as illustrated in FIGS. 10 and 11, part of the release layer 12 is removed by irradiation with the laser light 80, and the light-emitting element 130 is transferred from the first substrate 11 to the second substrate 21. The Galvano laser irradiation device 90 may be used for the irradiation with the laser light 80. Subsequently, as illustrated in FIG. 12, the light attenuating layer 13 is removed. Subsequently, as illustrated in FIG. 13, the light-emitting element 130 is transferred from the second substrate 21 to the wiring substrate 120 (the wiring substrate 31 in the first embodiment). In this way, as illustrated in FIG. 14, one or more light-emitting elements 130 disposed on the upper surface of the wiring substrate 120 can be prepared.

Light Reflective Member Disposing Step

Subsequently, as illustrated in FIG. 27A, a resist film 181 is disposed on the upper surface 121 of the wiring substrate 120 so as to surround a region in which the one or more light-emitting elements 130 are disposed. The shape of the resist film 181 is, for example, a frame shape in the plan view, and the thickness of the resist film 181 is approximately the same as the height of the light-emitting element 130.

Subsequently, an uncured light reflective resin material 182 is disposed on the plurality of light-emitting elements 130. The uncured light reflective resin material 182 includes, for example, a base material made of a light-transmissive resin material and a light reflective material contained in the base material.

Subsequently, a nozzle 200 is moved in the horizontal direction while a gas 183 is injected through the nozzle 200 from a direction substantially perpendicular to the upper surface of the wiring substrate 120. By spraying the gas 183 onto the upper surface 121 of the wiring substrate 120 in this way, the uncured light reflective resin material 182 is spread along the horizontal direction. The movement of the nozzle 200 may be repeated a plurality of times, for example. Thus, the uncured light reflective resin material 182 can be disposed between the wiring substrate 120 and the light-emitting elements 130 and between the light-emitting elements 130.

Subsequently, the light reflective resin material 182 disposed on the upper surface of the light-emitting element 130 is removed. The light reflective resin material 182 is removed by, for example, spraying solid carbon dioxide 184 through a nozzle 201 onto the light reflective resin material 182 disposed on the upper surface of the light-emitting element 130, as illustrated in FIG. 27B. Subsequently, the resist film 181 is removed by wet etching or the like.

Substrate Disposing Step

Subsequently, as illustrated in FIG. 22, the wiring substrate 120 is disposed above the package substrate 110. Preferably, the wiring substrate 120 is disposed on the heat dissipation member 114 disposed on the central portion of the package substrate 110. The wiring substrate 120 can be fixed to the package substrate 110 via a known joining member such as a metal paste. As the joining member, for example, a silicone silver paste is used.

Wire Connection step

Subsequently, the first pads 112 on the package substrate 110 and the external connection pads 122 on the wiring substrate 120 are electrically connected by the wires 160. In the wire connection step, it is preferable to connect one end of each of the wires 160 to the corresponding external connection pad 122 provided on the wiring substrate 120 and then connect the other end of each of the wires 160 to the corresponding first pad 112 provided on the package substrate 110. By connecting the wires 160 in the above order, the tops of the wires 160 can be easily disposed near the external connection pads 122. Thus, in the covering member disposing step to be described below, the amount of a resin disposed below the wires 160 can be reduced, and disconnection of the wires due to thermal expansion of the covering member 170 can be suppressed.

Wavelength Conversion Member Disposing Step

Subsequently, the wavelength conversion member 150 is disposed on the plurality of light-emitting elements 130. In the wavelength conversion member disposing step, for example, the wavelength conversion member 150 with a sheet shape processed to have a predetermined size in advance is prepared, and is disposed on the light-emitting elements 130. The wavelength conversion member 150 may be fixed to the light-emitting elements 130 via an adhesive of a resin or the like, or may be fixed using the tackiness or the like of the wavelength conversion member 150 instead of using an adhesive.

Covering Member Disposing Step

Subsequently, the covering member 170 that covers the wires 160 is disposed. The covering member disposing step includes a step of forming the first resin frame 171, a step of forming the second resin frame 172, and a step of forming the protective resin portion 173.

In the step of forming the second resin frame 172, an uncured second resin material is disposed along the region in which the plurality of light-emitting elements 130 are disposed, between the region in which the plurality of light-emitting elements 130 are disposed and the external connection pads 122 on the upper surface 121 of the wiring substrate 120. The second resin material can be disposed using, for example, a dispenser. The second resin material is, for example, a light-transmissive resin material.

In the step of forming the first resin frame 172, an uncured first resin material is disposed outside the first pads 112 on the upper surface of the package substrate 110. The first resin material can be disposed using, for example, a dispenser. The first resin material is, for example, a light-transmissive resin material. Preferably, the same resin material is used as the first resin material and the second resin material. Thus, in the first resin frame forming step and the second resin frame forming step, a step such as replacing the resin material can be omitted, and the takt time in manufacture can be shortened.

Subsequently, an uncured protective resin is disposed between the first resin material (first resin frame 171) and the second resin material (second resin frame 172) so as to cover the wires 160. The protective resin can be disposed using, for example, a dispenser. The protective resin is, for example, a resin material having light reflectivity and containing a light reflective material such as titanium oxide. As the protective resin, for example, a resin having a lower viscosity than the first resin material and the second resin material can be used. The protective resin is disposed over the wiring substrate 120 and the package substrate 110 and covers the lateral surfaces of the wiring substrate 120.

Subsequently, the first resin material, the second resin material, and the protective resin are solidified by a heating step to form the covering member 170 including the first resin frame 171, the second resin frame 172, and the protective resin portion 173. This results in the formation of the covering member 170 that protects the wires 160.

In this way, the light-emitting device 101 according to the present embodiment is manufactured.

An effect of the present embodiment is described. Also in the light-emitting device 101 according to the present embodiment, the lateral surfaces 133 (fifth surfaces) of the light-emitting element 130 are inclined with respect to the lower surface 132 (third surface) and spread in a direction from the lower surface 132 (third surface) toward the upper surface 131 (fourth surface). Thus, light generated in the light-emitting layer 182 of the light-emitting element 130 is efficiently reflected by the lateral surfaces 133, and is easily directed to the upper surface 131, which is a light-emitting surface. As a result, the light extraction efficiency of the light-emitting device 101 is increased.

In the step illustrated in FIG. 10, because the release layer 12 encloses the upper surface 131 of the light-emitting element 130 in the plan view, damage to the light-emitting element 130 due to the laser light 80 can be suppressed. Moreover, because the lower surface 132 and the lateral surfaces 133 of the light-emitting element 130 are covered with the light attenuating layer 13, damage to the light-emitting element 130 due to the laser light 80 can be further suppressed. As a result, the light-emitting device 101 has less damage to the light-emitting element 130 and high reliability.

The aforementioned embodiments and modified examples thereof are examples embodying the present disclosure, and the present disclosure is not limited to these embodiments and modified examples. For example, the addition, deletion, or change of some components or steps in each of the aforementioned embodiments and modified examples are also included in the present disclosure. The aforementioned embodiments and modified examples can be implemented in combination with each other.

Embodiments include the following aspects.

Supplementary Note 1

A method for manufacturing a light-emitting device, including
preparing a first structure including a first substrate having a first surface and a second surface on a side opposite the first surface, a release layer disposed on the first surface, and one or more light-emitting elements fixed to a side of the first surface of the first substrate via the release layer, the one or more light-emitting elements each having a third surface facing the release layer and a fourth surface on a side opposite the third surface, the fourth surface being larger than the third surface in a plan view, the release layer enclosing the fourth surface in the plan view;
preparing a second structure including a second substrate having an upper surface; and
transferring the one or more light-emitting elements from the first substrate to the second substrate by removing the release layer in such a manner that the release layer is irradiated with laser light from a second surface side of the first substrate in a state in which the first surface of the first substrate is opposed to the upper surface of the second substrate such that the one or more light-emitting elements are disposed between the first substrate and the second substrate.

Supplementary Note 2

The method for manufacturing a light-emitting device, according to supplementary note 1, wherein
the one or more light-emitting elements are a plurality of the light-emitting elements,
the release layer includes a plurality of layers each disposed forming a pair with the corresponding light-emitting element, and
each of the layers encloses the fourth surface of the corresponding light-emitting element in the plan view.

Supplementary Note 3

The method for manufacturing a light-emitting device, according to supplementary note 1, wherein
the one or more light-emitting elements are a plurality of the light-emitting elements, and
the release layer encloses all the fourth surfaces of the plurality of light-emitting elements in the plan view.

Supplementary Note 4

The method for manufacturing a light-emitting device, according to any one of supplementary notes 1 to 3, wherein
the first structure further includes a light attenuating layer disposed between the release layer and the light-emitting element, and
the method further includes, after the transferring, removing the light attenuating layer.

Supplementary Note 5

The method for manufacturing a light-emitting device, according to supplementary note 4, wherein
the light-emitting element further includes a fifth surface connecting the third surface and the fourth surface, and
the light attenuating layer covers the fifth surface.

Supplementary Note 6

The method for manufacturing a light-emitting device, according to supplementary note 4 or 5, wherein
the first structure further includes an adhesive layer disposed between the release layer and the light attenuating layer.

Supplementary Note 7

The method for manufacturing a light-emitting device, according to any one of supplementary notes 4 to 6, wherein
the preparing the first structure includes
   preparing a third structure including a support substrate, one or more semiconductor layered bodies disposed on the support substrate, electrode portions disposed on a surface of the one or more semiconductor layered bodies on a side opposite a surface facing the support substrate, and the light attenuating layer disposed on the support substrate and surrounding and holding the semiconductor layered body and each of the electrode portions, electrode surfaces of the electrode portions being exposed from the light attenuating layer;
   preparing a fourth structure including the first substrate and the release layer;
   bonding the electrode surfaces of the electrode portions in the third structure to the release layer in the fourth structure in a state in which the electrode surfaces of the electrode portions and
   the release layer are opposed to each other; and removing the support substrate after the bonding.

Supplementary Note 8

The method for manufacturing a light-emitting device, according to any one of supplementary notes 1 to 7, wherein
the one or more light-emitting elements are a plurality of the light-emitting elements, and
in the transferring, the laser light is emitted to portions of the release layer corresponding to the plurality of light-emitting elements while an emission direction of the laser light is controlled by a Galvano method.

Supplementary Note 9

The method for manufacturing a light-emitting device, according to supplementary note 8, wherein
the laser light is emitted obliquely to the third surface of the light-emitting element.

Supplementary Note 10

The method for manufacturing a light-emitting device, according to supplementary note 8 or 9, wherein
an intensity distribution of the laser light is a top hat distribution.

Supplementary Note 11

The method for manufacturing a light-emitting device, according to any one of supplementary notes 1 to 10, wherein
the second structure further includes an adhesive layer disposed on a side of the upper surface of the second substrate, and
in the transferring, the one or more light-emitting elements are bonded to the second substrate via the adhesive layer.

The present disclosure can be used, for example, for in-vehicle headlights, backlight devices for liquid crystal displays, various lighting fixtures, large displays, various display devices for advertisement, destination guide, or the like, projector devices, and the like.

1. A method for manufacturing a light-emitting device, the method comprising:
preparing a first structure comprising:
a first substrate having a first surface and a second surface on a side opposite the first surface,
a release layer disposed on the first surface, and
one or more light-emitting elements fixed to the first surface of the first substrate via the release layer, the one or more light-emitting elements each having a third surface facing the release layer and a fourth surface on a side opposite the third surface, the fourth surface being larger than the third surface in a plan view, wherein:
the release layer encloses the fourth surface in the plan view;
preparing a second structure comprising a second substrate having an upper surface; and
transferring the one or more light-emitting elements from the first substrate to the second substrate by removing the release layer in such a manner that the release layer is irradiated with laser light from a second surface side of the first substrate in a state in which the one or more light-emitting elements are disposed between the first substrate and the second substrate and the first surface of the first substrate is opposed to the upper surface of the second substrate.

2. The method for manufacturing a light-emitting device, according to claim 1, wherein:
the one or more light-emitting elements are a plurality of the light-emitting elements,
the release layer comprises a plurality of layers, each disposed on a corresponding one of the light-emitting elements, and
each of the layers encloses the fourth surface of the corresponding light-emitting element in the plan view.

3. The method for manufacturing a light-emitting device, according to claim 1, wherein:
the one or more light-emitting elements are a plurality of the light-emitting elements, and
the release layer is a continuous layer that encloses all the fourth surfaces of the plurality of light-emitting elements in the plan view.

4. The method for manufacturing a light-emitting device, according to claim 1, wherein:
the first structure further comprises a light attenuating layer disposed between the release layer and the light-emitting element, and
the method further comprises, after the step of transferring the one or more light-emitting elements, removing the light attenuating layer.

5. The method for manufacturing a light-emitting device, according to claim 4, wherein:
the light-emitting element further comprises a fifth surface connecting the third surface and the fourth surface, and
the light attenuating layer covers the fifth surface.

6. The method for manufacturing a light-emitting device, according to claim 4, wherein:
the first structure further comprises an adhesive layer disposed between the release layer and the light attenuating layer.

7. The method for manufacturing a light-emitting device, according to claim 4, wherein:
the step of preparing the first structure comprises:
preparing a third structure comprising:
a support substrate,
one or more semiconductor layered bodies disposed on the support substrate,
electrode portions disposed on a surface of the one or more semiconductor layered bodies on a side opposite a surface facing the support substrate, wherein:
the light attenuating layer is disposed on the support substrate and surrounds and holds the one or more semiconductor layered bodies and each of the electrode portions, and
electrode surfaces of the electrode portions are exposed from the light attenuating layer,
preparing a fourth structure comprising the first substrate and the release layer,
bonding the electrode surfaces of the electrode portions of the third structure to the release layer in the fourth structure in a state in which the electrode surfaces and the release layer are opposed to each other, and
after the step of bonding, removing the support substrate.

8. The method for manufacturing a light-emitting device, according to claim 1, wherein:
the one or more light-emitting elements are a plurality of the light-emitting elements, and
in the step of transferring the one or more light-emitting elements, the laser light is emitted to portions of the release layer corresponding to the plurality of light-emitting elements while an emission direction of the laser light is controlled by a Galvano method.

9. The method for manufacturing a light-emitting device, according to claim 8, wherein:
the laser light is emitted obliquely to the third surface of the light-emitting element.

10. The method for manufacturing a light-emitting device, according to claim 8, wherein:
an intensity distribution of the laser light is a top hat distribution.

11. The method for manufacturing a light-emitting device, according to claim 1, wherein:
the second structure further comprises an adhesive layer disposed on an upper surface side of the second substrate, and
in the step of transferring the one or more light-emitting elements, the one or more light-emitting elements are bonded to the second substrate via the adhesive layer.
